(19) United States
(12) Patent Application Publication
(10) Pub. No.: US 2008/0289576 A1
(43) Pub. Date: Nov. 27, 2008

(54) Plasma based ion implantation system

(75) Inventors: Young dong Lee, Suwon-si (KR); Yuri Tolmachev, Suwon-si (KR); Vladimir Volynets, Suwon-si (KR); Vasily Pashkovskiy, Suwon-si (KR); Andrey Ushakov, Suwon-si (KR); Gyeong Su Keum, Hwaseong-si (KR); Jae Hyun Han, Hwaseong-si (KR); Dong Cheol Kim, Suwon-si (KR); Hyung Chul Cho, Suwon-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 12/153,703

(22) Filed: May 22, 2008

(30) Foreign Application Priority Data
May 23, 2007 (KR) 10-2007-50132

(51) Int. Cl. C23C 16/44

(52) U.S. Cl. 118/723 I

(57) ABSTRACT

A plasma based ion implantation system capable of generating a capacitively coupled plasma having beneficial characteristics for an ion implantation, including the generation of necessary ions and radicals only for an ion implantation process instead of generating an inductively coupled plasma, which generates unnecessary ions and excessively dissociates radicals. The plasma based ion implantation system easily controls plasma ions implanted by cleaning a vacuum chamber, minimizes problems of unnecessary deposition and occurrence of contaminants and increases the number of components used only for the plasma ion implantion by reducing the deposition of polymer layer on a workpiece. The plasma based ion implantation system easily control uniformity of the plasma by using a flat type electrode, thereby easily ensuring uniformity of plasma ions implanted into the workpiece.

### CROSS-REFERENCE TO RELATED APPLICATIONS

This application claims the benefit of Korean Patent Application No. 10-2007-0050132 filed on May 23, 2007, in the Korean Intellectual Property Office, the disclosure of which is incorporated herein by reference.

### BACKGROUND

1. Field

The present invention relates to a plasma based ion implantation system. More particularly, the present invention relates to a plasma based ion implantation system capable of controlling an implantation of ions in an easy way as compared with an ion beam based ion implantation and reducing a problem of unnecessary deposition, and contamination on a surface of a wafer.

2. Description of the Related Art

A plasma based ion implantation (PBII) technology is a core technology, which is essentially necessary to develop a semiconductor device having a line width of 80 nm or below. The PBII technology is an ion doping technology for a Si device for realizing a CMOS (complimentary metal oxide semiconductor). As a line width of a semiconductor device gradually becomes narrow, a shallower junction depth is required and much more ions must be implanted so as to improve an operational speed of the semiconductor device. However, when using a conventional ion implantation technology based on ion beam line (BL), the productivity of the semiconductor devices is significantly reduced to satisfy the above process condition. The advantage of the plasma based ion implantation process, which represents an improved productivity as compared with that of a conventional BL scheme, is more prominent as the energy of ion implantation is lowered. Further, the plasma based ion implantation process can be performed by using equipment having a simple structure, a small size and a low price. In addition, the PBII scheme represents the substantially same result as compared with the BL scheme in terms of reproducibility and uniformity of the process and a generation of contaminants.

Recently, several types of plasma based ion implantation systems, such as U.S. Pat. Nos. 6,528,805 and 6,716,727, have been suggested. Most of the systems directly apply a square high-voltage pulse to a wafer to precisely adjust the energy of implanted ions. However, they represent difference in plasma generation schemes. The simplest scheme is to simultaneously generate plasma and implant the ions using the high voltage plasma applied to the wafer. According to other scheme, the high voltage pulse for generating plasma is used independently from the high voltage pulse for the ion implantation process. Recently, an inductively coupled plasma (ICP) generator is extensively used to generate plasma by using radio frequency (RF), instead of pulse.

The inductively coupled plasma (ICP) using RF has advantages of a wider process region and a lower occurrence of arching as compared with the plasma generated by using the high voltage pulse. The most advantageous point of the ion implantation process using the inductively coupled plasma is that the amount of ions and the energy can be adjusted independently from each other. That is, a density of plasma is adjustable by varying RF power application, thereby adjusting the amount of implanted ions. In addition, the high voltage pulse applied to the wafer enables the energy of ions to be adjusted.

In the case of the inductively coupled plasma generator, a metallic coil is installed on an upper portion of a chamber having a cylindrical shape for flowing current and is separated from the chamber while interposing a plate including insulating material therebetween. Such an inductively coupled plasma generator can generate high density plasma at various discharge conditions (for example, the type of gas, pressure, power, etc.).

Such an inductively coupled plasma generator easily generates high density plasma, so the inductively coupled plasma generator is generally used in various semiconductor manufacturing processes. However, if the inductively plasma generator is used for the PBII process, the following problems occur.

According to the PBII process, the plasma ions generated by the plasma generator are strongly accelerated by using the high voltage pulse such that the plasma ions can be deeply implanted into a surface of the wafer. In order to effectively perform the ion implantation process, plasma capable of facilitating the ion implantation by restraining dissociation of process gas and minimizing the formation of unnecessary layers on the surface of the wafer must be generated. However, the inductively coupled plasma has an electron temperature higher than that of capacitively coupled plasma, so that ions and radicals are excessively generated. As a result, the ions are unnecessarily implanted and process gas is excessively dissociated, thereby exerting a bad influence on the process efficiency such as deposition of the layer and generation of contaminants on the wafer surface. In addition, the ICP scheme forms a strong field around a coil, so that plasma is concentrated, causing a difficulty in controlling uniformity of plasma. Further, the use of dielectric causes a complicated structure of the plasma generator.

### SUMMARY

Accordingly, it is an aspect of the present invention to provide a plasma based ion implantation system capable of performing an effective discharge in a wide process region while solving the problem that an inductively coupled plasma generator represents, and improving the process efficiency and ensuring uniformity of plasma by reducing unnecessary ionization and dissociation.

Additional aspects and/or advantages of the invention will be set forth in part in the description which follows and, in part, will be apparent from the description, or may be learned by practice of the invention.

The foregoing and and/or other aspects of the present invention are achieved by providing a plasma based ion implantation system used for implanting ions on a surface of a workpiece, the plasma based ion implantation system comprising a vacuum chamber, in which the workpiece is disposed, having a reactive space for generating plasma; a first gas supply unit for supplying reactive gas into the vacuum chamber; a second gas supply unit for supplying cleaning gas into the vacuum chamber; an upper electrode and a lower electrode that are disposed in the vacuum chamber while facing each other; a radio frequency supply unit that supplies the upper electrode with radio frequency power to generate plasma; and a high voltage supply unit that supplies the workpiece and the lower electrode with a high voltage.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1A is a schematic view representing an plasma based ion implantation system according to a first embodiment of the present invention;

FIG. 1B is a schematic view representing an plasma based ion implantation system according to a second embodiment of the present invention;

FIG. 1C is an enlarged view representing a structure of an upper electrode shown in FIG. 1A;

FIG. 2 is a schematic view representing a plasma based ion implantation system according to a third embodiment of the present invention;

FIG. 3 is a view representing an arrangement of nozzles of a gas supply apparatus installed at both sidewalls of a vacuum chamber shown in FIG. 1A;

FIG. 4 is a schematic view representing a plasma based ion implantation system according to a fourth embodiment of the present invention;

FIGS. 5A to 5C are views schematically illustrating a shape of high voltage bias pulse applied to a workpiece;

FIG. 6 is a view representing a network configuration of the ion implantation system and an external system according to the present invention;

FIG. 7A is an enlarged view representing a voltage interconnection between the workpiece and a high voltage modulator and a voltage interconnection between a lower electrode and a DC power supply;

FIG. 7B is a view representing various geometric arrangements of multiple contact points between the workpiece and the high voltage modulator shown in FIG. 7A, in which the multiple contact points form a symmetrical configuration in axial and azimuth directions; and

FIG. 7C is a view representing an application of a negative constant voltage to the lower electrode by the DC power supply shown in FIG. 7A.

### DETAILED DESCRIPTION OF THE EMBODIMENTS

Reference will now be made in detail to the embodiments of the present invention, examples of which are illustrated in the accompanying drawings, wherein like reference numerals refer to the like elements throughout. The embodiments are described below to explain the present invention by referring to the figures.

Hereinafter, a preferred embodiment of the present invention will be described in detail with reference to the accompanying drawings.

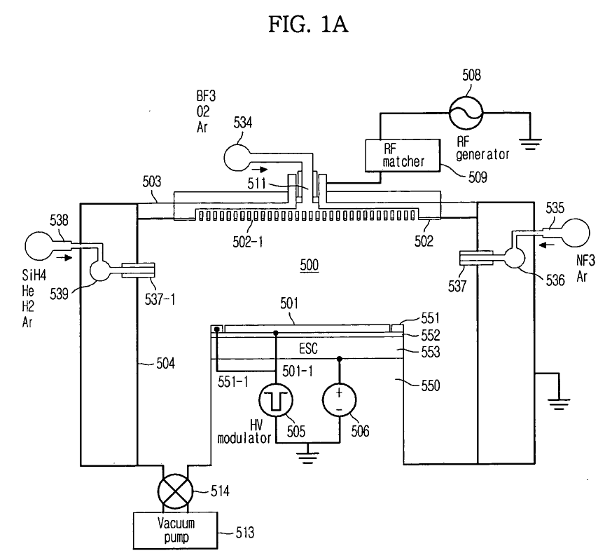

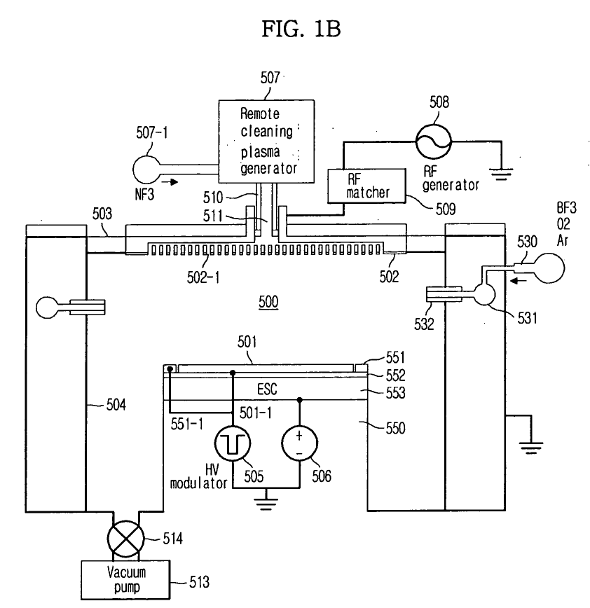

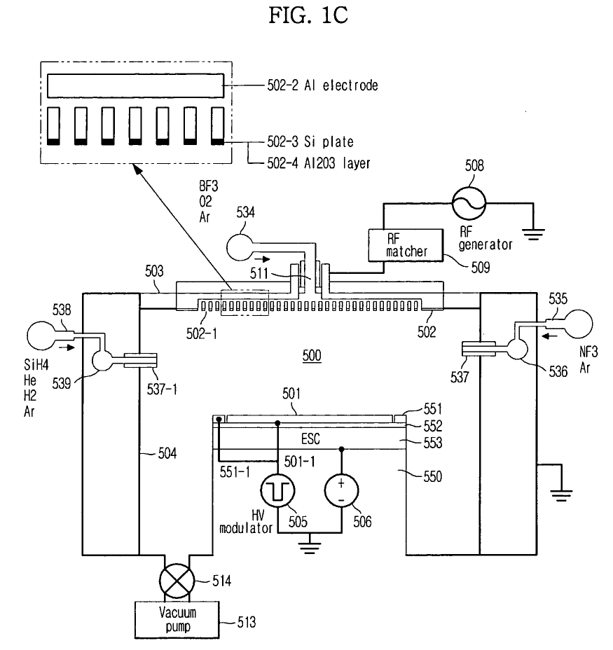

A plasma based ion implantation system according to an embodiment of the present invention is illustrated in FIGS. 1A to 4. As shown in FIG. 1A, a workpiece 501 is positioned on a lower electrode 553 in a vacuum chamber 500. The vacuum chamber 500 includes a sidewall 504 and a ceiling 503 having an RF capacitively coupled upper electrode 502. The sidewall 504 of the vacuum chamber 500 has an area larger than that of workpiece 501. The upper electrode 502 is disposed at a front portion of the workpiece 501 while being spaced apart from the workpiece 501 by a predetermined distance. Radio frequency supply units 508 and 509 are electrically connected to the upper electrode 502. The radio frequency supply units 508 and 509 include an RF generator 508 and a RF matcher 509. Reactive gas is transferred to a process zone through gas supply units 534, 535 and 538. As an example of the present invention, BF₃ and O₂ are transferred from an upper gas supply unit 534 through a plurality of shower head type gas injection ports 502-1 which are formed on the upper electrode 502. Such a gas is transferred to a side of the vacuum chamber 500 through a specific duct 511 formed in the middle of the upper electrode 502 and is distributed by the gas injection port 502-1. Other gases required for a process, chamber cleaning and phase control are transferred through a nozzle formed on the sidewall 504. The gas supply unit 535 provided at the sidewall 504 is used for transferring cleaning gases such as NF₃ and Ar and includes a gas distributing ring 536 and a gas nozzle 537. Other gas supply unit 538 includes a gas distribution ring 539 and a gas nozzle 537-1. The vacuum chamber 500 is maintained in an optimum pressure suitable for a discharge operation by means of a vacuum unit including a vacuum pump 513 and a vacuum valve 514.

Another example of the present invention is illustrated in FIG. 1B. As shown in FIG. 1B, a remote cleaning plasma generator 507 is used in order to clean the vacuum chamber 500. The remote cleaning plasma generator 507 is spaced apart from the vacuum chamber 500 and is connected to the inside of the vacuum chamber 500 through a specific duct 511. An insulator 510 is provided to prevent RF power from incoming into the remote cleaning plasma generator 507, Similarly to FIG. 1A, the cleaning gas such as NF₃ is transferred from an upper gas supply unit 507-1 and the reactive gas such as BF₃ is transferred from a gas supply unit 530 formed on the sidewall 504 and provided with a gas distribution ring 531 having an annular shape and a gas nozzle 532.

A workpiece 501 is electrically connected to high voltage supply units 505 and 506. The high voltage supply units 505 and 506 include a high voltage modulator 505, which applies a specific square high voltage to the workpiece 501, and a DC power supply 506, which applies a constant voltage to a lower electrode 553. The high voltage modulator 505 and the workpiece 501 are electrically connected with each other through a specific interconnection and a transferring member which are represented as reference numerals of 501-01 and 551-1, respectively. The workpiece 501 is attached to a support 550 by a static electricity formed between the workpiece 501 and the lower electrode 553 by means of an insulator layer 552. The DC power supply 506 is connected to the lower electrode 553.

FIG. 1C is a detailed view representing the upper electrode 502 which has a surface including Al and is covered with a specific material exerting an influence on a implantation characteristic of ions. According to an embodiment of the present invention, the upper electrode 502 is covered with Si 502-3 and includes the gas injection port 502-1 disposed at a position corresponding to the upper electrode 502. Alternately, an Al₂O₃ oxide coating layer having a thickness of 10 μm to 50 μm is used in order to prevent the workpiece 501 from being contaminated by Al.

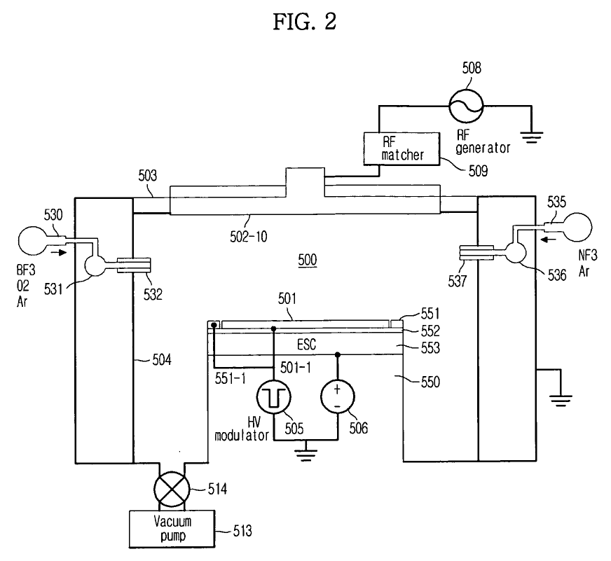

Referring to FIG. 2, an upper electrode 502-10 does not have a shower head shape and the reactive gas such as BF₃, O₂ and Ar are transferred from the gas supply unit 530 of a first sidewall to the vacuum chamber 500 through a gas nozzle 532. The cleaning gas such as NF₃ and Ar is transferred from the gas supply unit 535 of a second sidewall to the vacuum chamber 500.

The plasma is formed in the vacuum chamber 500 by the upper electrode 502-10 which is connected to the RF generator 508 through the proper RF matcher 509.

Meanwhile, in FIGS. 1A to 2, a distance between the upper electrode and the lower electrode is set to a predetermined value limited by the lower electrode and is determined by electrical parameters of an electric pulse.

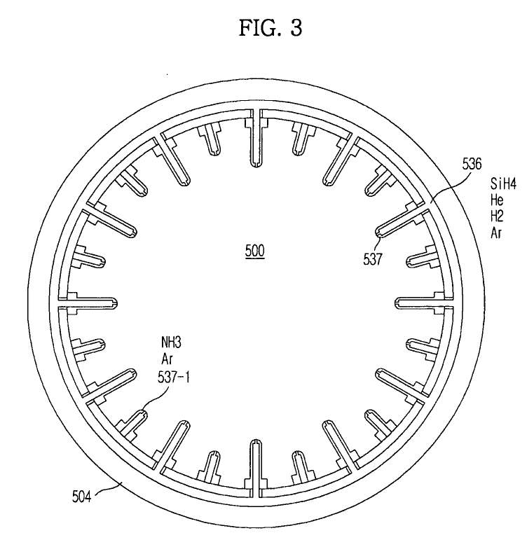

FIG. 3 represents an example of the gas nozzle formed at the sidewall of the vacuum chamber 500. As shown in FIG. 3, openings of the nozzle are uniformly disposed along the sidewall 504 of the vacuum chamber 500 in such a way that the gas nozzles 537 for the reactive gas including SiH₄, He, H₂ and Ar are disposed on a first plane, and the gas nozzles 537-1 for the cleaning gas including NH₃ and Ar are disposed on a second plane different from the first plane. In order to minimize a shading region in which the cleaning gas is not transferred, each gas nozzle 537-1 for the cleaning gas is disposed corresponding to each gas nozzle 537 for the reactive gas. A length of the nozzle is optimized according to the condition of the vacuum chamber 500. For example, the nozzle has a length of 10 to 80 mm.

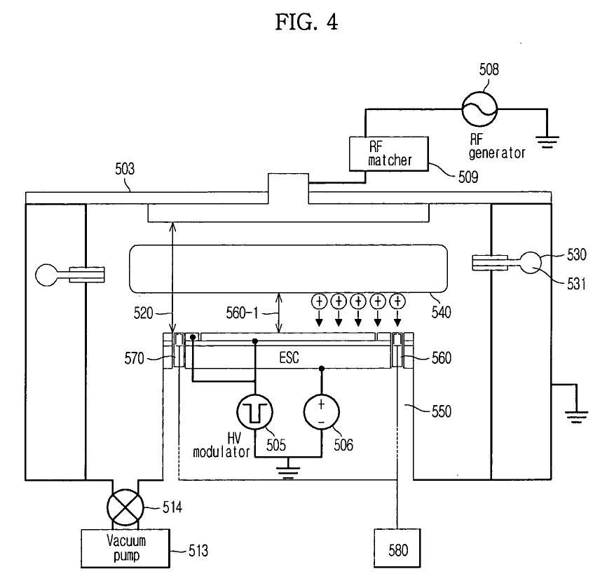

FIG. 4 represents a distance 520 between the upper electrode and the lower electrode serving as important elements when designing the vacuum chamber 500. The distance is determined such that the distance exceeds plasma sheath thickness during the application of the high voltage pulse. The plasma sheath thickness is determined according to the child-langumuir law such as a following equation 1 or 2.

$$\begin{matrix}j = \frac{4}{9} ɛ {o ( \frac{2 e}{M} )}^{1 / 2} \frac{{Vo}^{3 / 2}}{{s}^{2}} & Equation 1 \\ J ( A \text{/} {cm}^{2} ) = 2.33 \cdot {10}^{- 6} \cdot \frac{{V ( volts )}^{3 / 2}}{\sqrt{M ( kg ) \cdot {s ( cm )}^{2}}} & Equation 2\end{matrix}$$

Here, j is a current density, e is an electric charge of an electron, M is a mass of an electron, V₀ is potential difference between the electrodes, and s is a distance between the electrodes.

A maximum moving distance of ions from a boundary of the plasma can be obtained. An ion current of the parameters for the ion implantation is in a range of 1 to a few A (ampere).

A gap between the plasma and the electrode is determined as 20 to 30 mm based on the parameters. In detail, the measurement represents that the plasma may move from the electrode by 24 mm in the case of B and move by 17 mm in the case of BF₂ when −5000V of voltage is applied to the electrode and the current density is 1 mA/cm².

When the voltage of −10000V is applied, the gap size may increase up to 68 mm and 48 mm, respectively, in a state in which the current density remains at the same level. Considering that the general capacitively coupled plasma reaction apparatus has a gap of 0 to 30 mm, when the gap is large in the plasma based ion implantation system, the discharge may begins between the upper electrode and the walls, other than between the upper electrode and the lower electrode.

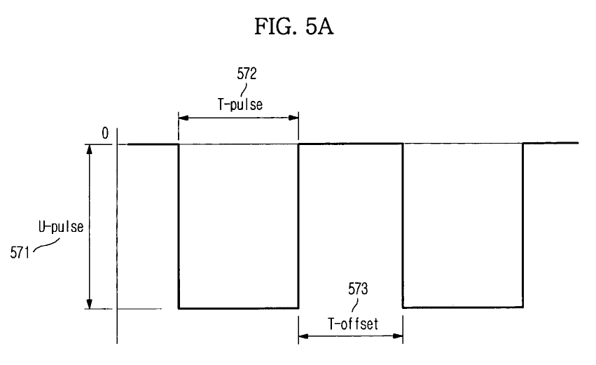

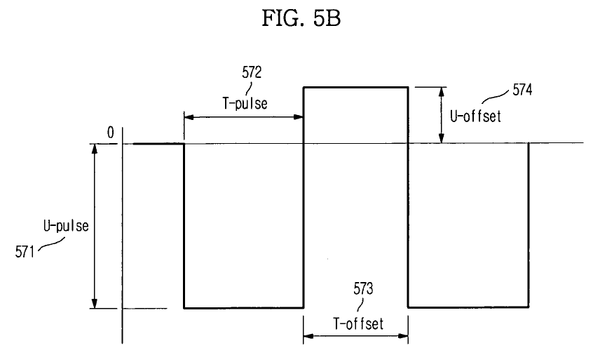

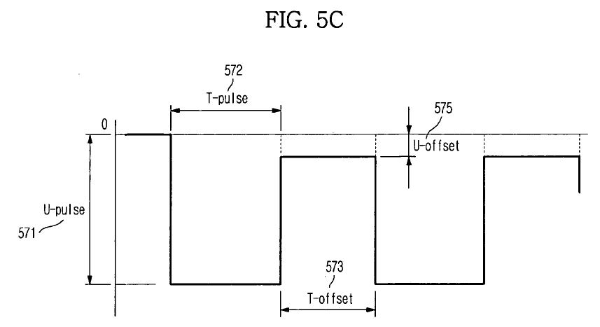

According to an operational process of the present invention, the reactive gas is injected into the process chamber 500 through a series of the nozzles 532, 537, 502-1 shown in FIGS. 5A and 5B, and RF power is applied to the upper electrode 502 through the RF matcher 509 corresponding to the RF generator 508. When the power is applied, an oscillating electromagnetic field is filled in a space of the vacuum chamber 500 to which gas is transferred, and a capacitive coupling operation begins between the upper electrode 502 and the conductive chamber wall 504, and among the upper electrode 502, workpiece 501 and other structures (for example, a ring 551 surrounding the workpiece 501) into which implanted ions are directed. Accordingly, a capacitive sheath is formed between the gas having an initial zero potential and the upper electrode 502. RF current passes through the sheath to cause a stochastic collisionless heating, in which electrons do not collide with each other in a random way, and ohmic heating in the bulk gas plasma.

If the workpiece 501 includes crystalline silicon into which p-type conductive impurities are partially implanted, the gas supply unit 530 or 534 supplies BF₃ including boron as an impurity. In general, dopant containing gas represents a chemical material that includes boron serving as a p-type conductive impurity in silicon and impurities such as a volatile component. In the plasma including fluoride of dopant gas such as BF₃, various ion components, such as BF2+, BF+, B+, F+ and F−, etc., are distributed. All kinds of components are accelerated by passing through the sheath and implanted into a surface of the workpiece 501.

A dopant atom is generally dissociated from the volatile component when colliding with the workpiece 501 at a higher energy.

A dopant component is formed in the plasma 540 generated in a reaction space in the vacuum chamber 500. In order to direct the doping component toward the workpiece 501, a continuous high voltage pulse having a negative property of 1 to 10 kV is applied from the high voltage modulator 505 to the lower electrode 550, particularly to the workpiece 501 and the conductive ring 551 surrounding the workpiece 551. The conductive ring 551 allows the electrostatic field to be uniformly formed in a region adjacent to the workpiece 501. If the electrostatic field is not uniform, the ion component directing toward the workpiece 501 may deviate from the surface of the workpiece 501 or slantingly collides with the surface of the workpiece 551, thereby lowering the implantation effect on a corner area of the workpiece 501 or lowering the implantation effect.

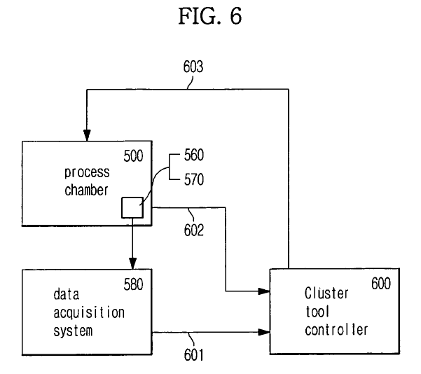

As shown in FIG. 6, in several cases, the upper electrode 502 is covered with specific layers including different conductive materials. This is for reducing the contaminant on the inner surface of the vacuum chamber 500 or the surface of the workpiece 501. As an example, a shallow positive dielectric layer 502-4 including Al₂O₃ is used to protect the vacuum chamber 500 from Al particles falling to the workpiece 501. As a result of biasing on the dielectric layer, the voltage is not high at the front of the plate. Since the plate has a shallow depth of 10 to 50 μm, the plate has high capacitance so that it can be charged within a predetermined time during which high voltage is applied from the high voltage modulator 505 to the plasma. The dielectric layer can be discharged during a pulse-off time. As another example, the Si layer 502-3 is used on the Al electrode. The Si is considered as a conductor that has a low bias voltage at a front portion thereof and prevents a sputtering from actively occurring.

As shown in FIGS. 1A and 3, the gas nozzles 537 and 537-1 transfer various types of gas into the vacuum chamber 500. A set of gas nozzles is used to transfer the cleaning gas such as NF₃ for cleaning the apparatus. In this case, the remote cleaning plasma generator 507 is not necessary. In addition, the gas nozzle 537-1 is used for purge gas (Ar) of the vacuum chamber 500 and a gas line, and dilute gas (He) for transferring SiH₄. In addition, the gas nozzle 537-1 is used for cleaning and controlling the chamber 500 by use of H₂. The H₂ removes F through a reaction of H₂+F→HF+H. Further, the SiH₄ is transferred into the vacuum chamber 500 without being discharged in order to remove the excessive F from the walls of the chamber 500. In several cases, the reactive gas is transferred from the sidewall to clean the chamber 500 through the shower head.

As shown in FIG. 4, when the high voltage pulse is applied, the sheath 560-01, in which the ion components are accelerated, is formed between the workpiece 501 and the bulk plasma 540. When 10 kV of voltage is applied according to a specific technology condition, the sheath 560-1 has a width of 20 to 70 mm.

FIGS. 5A to 5C schematically represent the shapes of high voltage bias pulse applied to the workpiece 501. The pulse has a negative polarity. A U-pulse 571 has a magnitude of 1 to 10 kV, and a T-pulse 572 has a duration time of 1 to 10 μs. A T-offset 573 has a pulse interval of 10 to 100 μs. A rising time and a falling time of the applied pulse are about 50 to 100 ns.

During a cycle of the T-offset 573, the voltage is applied to the workpiece 501. At the same time, a non-zero offset voltage is applied as shown in FIGS. 5B and 5C. As shown in FIG. 5B, a U-offset non-zero positive voltage 574 is applied, and as shown in FIG. 5C, a U-offset non-zero negative voltage 575 is applied. The application of offset voltage solves the problem related to deposition of a polymer layer. One of advantages in the implantation system using the pulse is that the polymer layer is deposited during a temporary stop time between the pulses. Accordingly, an etching can be properly performed on the surface of the substrate while preventing the surface from being contaminated by applying a negative bias of 0 to 200V.

Since energy of the accelerated doping ions is reduced while passing through the sheath area due to a collision, the energy does not correspond to the voltage applied to the workpiece 501. In a pressure condition of 20 mTorr, even if the voltage applied to the workpiece 501 is 5 to 7 kV, the effective energy of the ion components colliding with the workpiece 501 is 1 to 2 kV. Accordingly, an independent system may be required for monitoring the ion energy. Since the total implantation effect is determined depending on the amount of ions deposited on the surface of the workpiece 501, the measurement of the ion current is important. As shown in FIG. 4, the measurement of the ion energy and the ion current are accomplished by a specific technology such as a diagnostic system 560 and 570 including a faraday cup 560 and an ion energy analyzer 570. The diagnostic systems 560 and 570 are connected with a data acquisition system 580 that traces and monitors a relevant data in real time.

A conductivity of the implantation area of the semiconductor is determined according to a junction depth, and a volume concentration of the implanted dopant components which is activated after a sequential annealing process. The junction depth is determined by the bias voltage, which is applied to the workpiece 501 and controlled by the voltage level of the high voltage modulator 505. The dopant concentration of the implantation area is determined by an implantation moment of dopants and a dopant ion flux on the surface of the workpiece 501 during the duration time of ion flux. The total ion flux is called an ion dose. The dopant ion flux is determined by a magnitude of the RF power emitted from the RF generator 508. Such an arrangement allows the conductivity of the implantation area and the junction depth to be independently controlled. In general, the control parameter such as a power output level of the high pressure modulator 505 and the RF generator 508 is selected to satisfy a target value of the conductivity and the junction depth and to reduce the implantation time. In order to directly control the ion energy and the dose, the bias electrode has the specific diagnostic system such as the faraday cup 560 for measuring the ion dose and the ion energy analyzer 570 for measuring the ion energy.

The present invention provides a method capable of preventing a contamination of the chamber 500 by periodically cleaning the inner surface of the vacuum chamber 500. In the process cycle, etching components are dissociated by the remote cleaning plasma generator 507 based on the discharge of etching gas such as NF₃. In addition, the activating fluoride is reacted with a contaminated portion of the walls 504 of the vacuum chamber 500 or the lower electrode 553 to remove a polymer film contaminant and is pumped out through the pumping apparatuses 513 and 514. In this case, the inner surface of the vacuum chamber 500 maintains a constant conductivity, so that a self biasing is prevented from occurring on the dielectric film formed on the walls 504 of the vacuum chamber 500, thereby reducing the risk of losing power and/or the occurrence of the arc.

In addition, as shown in FIG. 6, the present invention includes the data acquisition system 580, which receives data from the diagnostic systems 560 and 570, and is connected to a cluster tool controller 600 which controls and monitors the parameter of the process chamber through a computer network. The reference numerals 601 to 603 represent the data lines.

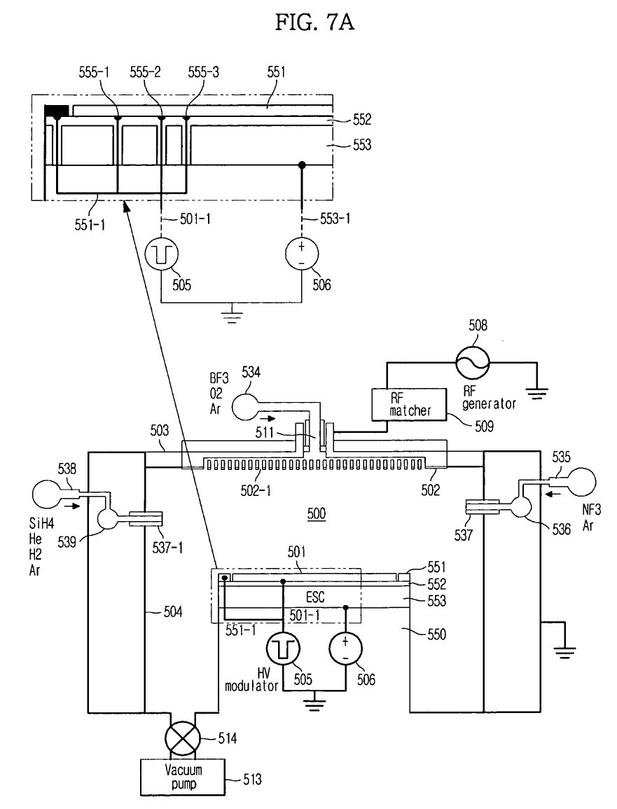

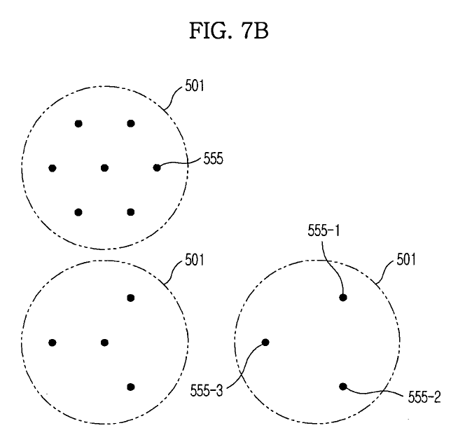

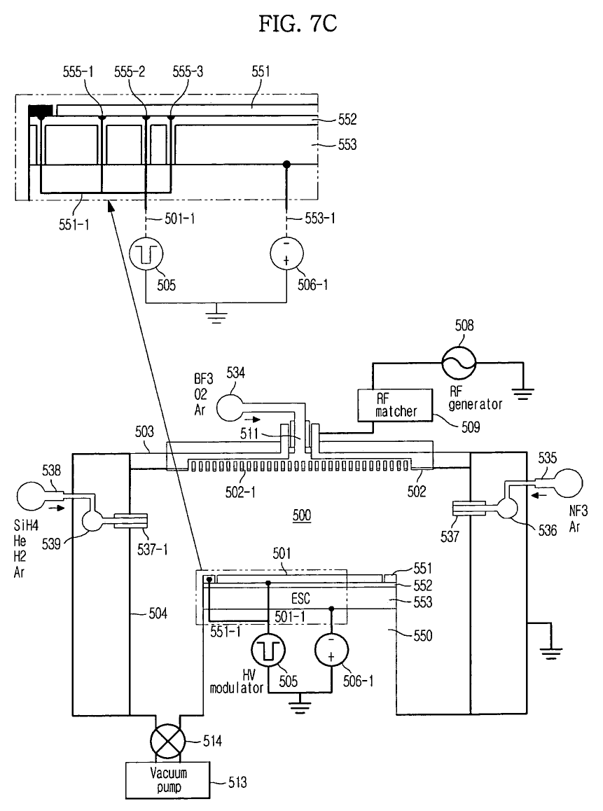

As shown in FIG. 7A, the high voltage modulator 505 is connected to the workpiece 501 at multiple contact points 555-1, 555-2 and 555-3, and. as shown in FIG. 7B, the multiple contact points form a symmetrical configuration when making contact with the workpiece 501.

As shown in FIG. 7A, the voltage applied to the lower electrode 553 from the DC power supply 506 through the interconnection 553-1 has a positive polarity that reduces the voltage applied to a ground unit of the system from the dielectric layer 552. Meanwhile, in the case of FIG. 7C, the voltage generated from a DC power supply 506-1 has a negative polarity relative to a ground potential such that the entire voltage applied to the workpiece 501, the dielectric layer 552, and the lower electrode 553 can be reduced. For example, if the voltage pulse from the high voltage modulator 505 has a magnitude of −10 kV and the voltage from the DC power supply 506 has a magnitude of −1 kV, the total voltage difference is just 9 kV. The voltage difference between the two electrodes is high enough to provide a force for an electrostatic clamping. Between the high voltage pulses, the workpiece 501 has a potential of zero and the lower electrode 553 has a potential of −1 kV, so that the electrostatic system passing through the dielectric layer 552 aligned in opposition to the workpiece 501 still exists such that the workpiece 501 can be clamped at its original position.

According to the present invention, the capacitively coupled plasma has advantageous characteristics for an ion implantation process as compared with inductively coupled plasma which excessively generates unnecessary ions and causes dissociation of radicals due to the high electron temperature. The capactively coupled plasma generates the ions and radicals required only for the ion implantation process and easily controls the implanted ions in plasma, and reduces the deposition of polymer layer on a surface of the workpiece, thereby reducing the problem derived from unnecessary deposition and contaminants. In addition, the capacitively coupled plasma increases the density of components which are used for the plasma based ion implantation and ensures uniformity of the plasma ions implanted into the workpiece by easily controlling uniformity of plasma through a flat type electrode.

In addition, according to the present invention, parameters of plasma and ion energy are independently controlled. The plasma is ignited by capacitively coupled plasma generator and is stably maintained.

In addition, the cleaning process for the vacuum chamber is essentially necessary regardless of the types of the plasma generators, and low energy polymer components always exist. Accordingly, a method for maintaining electrical characteristics of the vacuum chamber must be considered when designing the chamber. According to the present invention, in order to efficiently clean the chamber, a remote cleaning plasma generator and other relevant system are suggested. For the cleaning process and the balance of power distribution, a duct of the remote cleaning plasma generator is integrally formed with an RF transporting structure for the capacitively coupled plasma, so that the cleaning process and the power distribution from the RF generator can be preferably achieved.

In addition, according to the present invention, a specific voltage pulse is provided to control a state of the surface of the workpiece. A square high voltage pulse is applied to precisely distribute ion energy. Simultaneously, a positive voltage offset or a negative voltage offset is applied between main pulses to control the deposition of ions and radicals on the workpiece, thereby preventing a polymer layer from being deposited on the workpiece and preventing accelerated ions from exerting a bad effect on the subsequent ion implantation.

In addition, according to the present invention, the higher frequency input from the RF generator controls a plasma concentration and an ion flux on the surface of the workpiece without exerting a bad influence on a sheath voltage or the ion energy. The higher frequency of 30 MHz or 50 Hz or above can lead to a better result and significantly widen the coverage of use in several cases having a source power frequency of 160 MHz or 200 MHz.

In addition, according to the present invention, an area of a dielectric ceiling is reduced as compared with a dielectric dome of the inductively coupled plasma (ICP) discharge. In the case of the inductively coupled plasma, a surface of the dome is easily sputtered by a high energy ion which applies an impact to the surface of the dome.

Although a few embodiments have been shown and described, it would be appreciated by those skilled in the art that changes may be made in these embodiments without departing from the principles and spirit of the invention, the scope of which is defined in the claims and their equivalents.

What is claimed is:

1. A plasma based ion implantation system used for implanting ions on a surface of a workpiece, the plasma based ion implantation system comprising:
a vacuum chamber, in which the workpiece is disposed, having a reactive space for generating plasma;
a first gas supply unit for supplying reactive gas into the vacuum chamber;
a second gas supply unit for supplying cleaning gas into the vacuum chamber;
an upper electrode and a lower electrode that are disposed in the vacuum chamber while facing each other;
a radio frequency supply unit that supplies the upper electrode with radio frequency power to generate plasma; and
a high voltage supply unit that supplies the workpiece and the lower electrode with a high voltage.

2. The plasma based ion implantation system according to claim 1, wherein the first gas supply unit is installed on a sidewall of the vacuum chamber.

3. The plasma based ion implantation system according to claim 1, wherein the first gas supply unit is installed on a sidewall and a ceiling of the vacuum chamber.

4. The plasma based ion implantation system according to claim 1, wherein the second gas supply unit is installed on a sidewall of the vacuum chamber.

5. The plasma based ion implantation system according to claim 1, wherein the second gas supply unit provides the cleaning gas including NF₃.

6. The plasma based ion implantation system according to claim 1, wherein the first gas supply unit and the second gas supply unit are installed on the sidewall of the vacuum chamber while facing each other.

7. The plasma based ion implantation system according to claim 1, further comprising a pumping unit for pumping by-products of chemical reaction dilute gas, cleaning gas and other gas out of the vacuum chamber.

8. The plasma based ion implantation system according to claim 1, further comprising a conductive ring surrounding the workpiece.

9. The plasma based ion implantation system according to claim 1, further comprising a diagnostic apparatus which is installed at a side of the workpiece to measure and diagnose ion current and ion energy in the vacuum chamber.

10. The plasma based ion implantation system according to claim 8, wherein the conductive ring is electrically connected to a high voltage modulator.

11. The plasma based ion implantation system according to claim 1, wherein the high voltage supply unit includes a high voltage modulator and a DC power supply.

12. The plasma based ion implantation system according to claim 11, wherein the high voltage modulator applies a high voltage pulse to the workpiece.

13. The plasma based ion implantation system according to claim 12, wherein the high voltage modulator applies square high voltage pulse to the workpiece, in which the square high voltage pulse has a magnitude of at least 0.1 kV, a duration time of at least 0.1 μs and a pulse interval of at least 0.5 μs wherein, during an operation, the square high voltage pulse has magnitude of 1 kV to 10 kV, a duration time of 1 μs to 10 μs and a pulse interval of 10 μs to 100 μs at a predetermined point of a continuous operational range.

14. The plasma based ion implantation system according to claim 13, wherein the high voltage modulator applies the high voltage pulse to the workpiece during the high voltage pulse interval under conditions that a positive electrostatic voltage offset applied by the DC power supply is within an interval range of 0V to 1000V or a negative electrostatic voltage offset applied by the DC power supply is within an interval range of 0V to −10000V.

15. The plasma based ion implantation system according to claim 14, wherein a rising time and a falling time are shorter than the duration time of the high voltage pulse.

16. The plasma based ion implantation system according to claim 1, wherein the DC power supply is electrically connected to the workpiece while being charged with negative polarity to provide a clamping electrostatic force.

17. The plasma based ion implantation system according to claim 12, wherein the workpiece is connected at a plurality of contact points to an interconnection that transfers the high voltage pulse from the high voltage modulator.

18. The plasma based ion implantation system according to claim 17, wherein the plural contact points have a symmetrical configuration in axial and azimuth directions on a surface of the workpiece.

19. The plasma based ion implantation system according to claim 1, wherein a portion of the upper electrode is covered with an additional layer such as an Al₂O₃ layer or a Si layer.

20. The plasma based ion implantation system according to claim 1, wherein a sidewall of the vacuum chamber has an area larger than that of the workpiece.

21. The plasma based ion implantation system according to claim 1, wherein in a case in which the first gas supply unit is installed in a ceiling of the vacuum chamber, a remote cleaning plasma generator is installed on a gas supply path of the first gas supply unit from an outside of the vacuum chamber, in which the remote cleaning plasma generator is connected to a gas injection port formed on the upper electrode through a special duct.

22. The plasma based ion implantation system according to claim 21, wherein the special duct includes dielectric material such as alumina ceramic.

23. The plasma based ion implantation system according to claim 1, wherein the RF supply unit includes a RF matcher and an RF generator.

24. The plasma based ion implantation system according to claim 23, wherein the RF generator generates a radio frequency in a range of 500 MHz to 200 MHz.

25. The plasma based ion implantation system according to claim 1, wherein the workpiece is disposed on a dielectric layer formed on the surface of the lower electrode.
